(19) United States
(12) Patent Application Publication
(10) Pub. No.: US 2024/0090259 A1
(43) Pub. Date: Mar. 14, 2024

(54) DISPLAY APPARATUS

(71) Applicant: SAMSUNG DISPLAY CO., LTD., Yongin-si (KR)

(72) Inventors: Sungeun LEE, Yongin-si (KR); Kyungho KIM, Yongin-si (KR); Younjoon KIM, Yongin-si (KR); Jonghyun CHOI, Yongin-si (KR)

(21) Appl. No.: 18/122,376

(22) Filed: Mar. 16, 2023

(30) Foreign Application Priority Data
Sep. 13, 2022 (KR) 10-2022-0115104

(51) Int. Cl. H10K 59/121; H10K 59/131

(52) U.S. Cl. CPC H10K 59/1213; H10K 59/131; H10K 2102/311

(57) ABSTRACT

A display apparatus includes: a substrate including pixel circuit areas, line areas arranged between the pixel circuit areas, and non-line areas which are arranged between the line areas and in which no line is arranged; a pixel circuit arranged in the pixel circuit areas and including at least one thin film transistor; a plurality of lines arranged in the pixel circuit areas and the line areas; and a display element including a pixel electrode connected to the pixel circuit, where in a plan view an area of the pixel electrode is greater than an area in which the pixel circuit is arranged.

This application claims priority to Korean Patent Application No. 10-2022-0115104, filed on Sep. 13, 2022, and all the benefits accruing therefrom under 35 U.S.C. § 119, the content of which in its entirety is herein incorporated by reference.

### BACKGROUND

### 1. Field

One or more embodiments relate to display apparatuses.

### 2. Description of the Related Art

A display panel has been used for various purposes. Also, as the display panel has become thinner and lighter, its range of use has widened.

As the area occupied by a display area in the display panel has been expanded, components should be arranged in a relatively narrow outer area. Thus, when a crack occurs due to the arrangement of the components, the reliability and display quality of a display apparatus may be degraded.

### SUMMARY

One or more embodiments include a display apparatus with improved reliability and display quality.

Additional aspects will be set forth in part in the description which follows and, in part, will be apparent from the description, or may be learned by practice of the presented embodiments of the disclosure.

According to one or more embodiments, a display apparatus includes: a substrate including pixel circuit areas, line areas arranged between the pixel circuit areas, and non-line areas which are arranged between the line areas and in which no line is arranged; a pixel circuit arranged in the pixel circuit areas and including at least one thin film transistor; a plurality of lines arranged in the pixel circuit areas and the line areas; and a display element including a pixel electrode connected to the pixel circuit; where in a plan view an area of the pixel electrode is greater than an area in which the pixel circuit is arranged.

In an embodiment, the pixel circuit areas and the line areas may be alternately arranged in a first direction and a second direction intersecting with the first direction.

In an embodiment, an area of one of the non-line areas may be about 10 percentages (%) or more of an area of one of the pixel circuit areas in the plan view.

In an embodiment, the display apparatus may include a folding area and a non-folding area, and in the plan view an area of one of the pixel circuit areas in the folding area may be the same as an area of one of the pixel circuit areas in the non-folding area.

In an embodiment, each of the pixel circuit areas may include two pixel circuits.

In an embodiment, the display apparatus may further include an inorganic insulating layer defining a groove therein in the line areas.

In an embodiment, the pixel electrode may at least partially overlap the line areas in the plan view.

In an embodiment, the plurality of lines may include a first line extending in a first direction and a second line extending in a second direction intersecting with the first direction, the first line may be arranged in the same layer as a gate electrode of the thin film transistor, and the second line may be arranged in a different layer from the first line.

In an embodiment, the second line may be arranged farther from an upper surface of the substrate than the first line in a thickness direction.

In an embodiment, the first line may include a scan line, and the second line may include a data line.

According to one or more embodiments, a display apparatus including a folding area and a non-folding area includes: a substrate including pixel circuit areas, line areas arranged between the pixel circuit areas, and non-line areas which are arranged between the line areas and in which no line is arranged; a pixel circuit arranged in the pixel circuit areas and comprising at least one thin film transistor; a plurality of lines arranged in the pixel circuit areas and the line areas; and a display element including a pixel electrode connected to the pixel circuit, where in a plan view an area of one of the pixel circuit areas in the folding area is the same as an area of one of the pixel circuit areas in the non-folding area.

In an embodiment, an area of the pixel electrode may be greater than an area in which the pixel circuit is arranged in the plan view.

In an embodiment, the pixel circuit areas and the line areas may be alternately arranged in a first direction and a second direction intersecting with the first direction.

In an embodiment, an area of one of the non-line areas may be about 10% or more of an area of one of the pixel circuit areas in the plan view.

In an embodiment, each of the pixel circuit areas may include two pixel circuits.

In an embodiment, the display apparatus may further include an inorganic insulating layer defining a groove therein in the line areas.

In an embodiment, the pixel electrode may at least partially overlap the line areas in the plan view.

In an embodiment, the plurality of lines may include a first line extending in a first direction and a second line extending in a second direction intersecting with the first direction, the first line may be arranged in the same layer as a gate electrode of the thin film transistor, and the second line may be arranged in a different layer from the first line.

In an embodiment, the second line may be arranged farther from an upper surface of the substrate than the first line in a thickness direction.

In an embodiment, the first line may include a scan line, and the second line may include a data line.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a perspective view schematically illustrating a display apparatus according to an embodiment;

FIG. 2 is a perspective view schematically illustrating a folded form of a display apparatus according to an embodiment;

FIG. 3A is an equivalent circuit diagram schematically illustrating a pixel circuit according to an embodiment;

FIG. 3B is an equivalent circuit diagram schematically illustrating a pixel circuit according to an embodiment;

FIG. 4 is a plan view schematically illustrating a pixel circuit and a pixel arranged in a display apparatus according to an embodiment;

FIG. 5 is a plan view schematically illustrating a pixel circuit area and a line area arranged in a display area of a display apparatus according to an embodiment;

FIG. 6 is an arrangement diagram schematically illustrating a form in which a pixel electrode connected to a pixel circuit is arranged according to an embodiment;

FIG. 7 is an arrangement diagram schematically illustrating a form in which a pixel electrode connected to a pixel circuit is arranged according to an embodiment;

FIG. 8 illustrates, in a cross-sectional view taken along line I-I′ of FIG. 5, a configuration in which an organic light emitting diode is arranged; and

FIG. 9 is a cross-sectional view schematically illustrating a display apparatus according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

The disclosure may include various embodiments and modifications, and certain embodiments thereof are illustrated in the drawings and will be described herein in detail. The effects and features of the disclosure and the accomplishing methods thereof will become apparent from the embodiments described below in detail with reference to the accompanying drawings. However, the disclosure is not limited to the embodiments described below and may be embodied in various modes.

Hereinafter, embodiments will be described in detail with reference to the accompanying drawings, and in the following description, like reference numerals will denote like elements and redundant descriptions thereof will be omitted for conciseness.

It will be understood that although terms such as “first” and “second” may be used herein to describe various elements, these elements should not be limited by these terms and these terms are only used to distinguish one element from another element.

As used herein, the singular forms “a,” “an,” and “the” are intended to include the plural forms as well, unless the context clearly indicates otherwise.

Also, it will be understood that the terms “comprise,” “include,” and “have” used herein specify the presence of stated features or elements, but do not preclude the presence or addition of one or more other features or elements.

It will be understood that when a layer, region, area, component, or element is referred to as being “on” another layer, region, area, component, or element, it may be “directly on” the other layer, region, area, component, or element or may be “indirectly on” the other layer, region, area, component, or element with one or more intervening layers, regions, areas, components, or elements therebetween.

Sizes of elements in the drawings may be exaggerated for convenience of description. In other words, because the sizes and thicknesses of elements in the drawings are arbitrarily illustrated for convenience of description, the disclosure is not limited thereto.

Also, herein, the x axis, the y axis, and the z axis are not limited to three axes of the rectangular coordinate system and may be interpreted in a broader sense. For example, the x axis (x direction), the y axis (y direction), and the z axis (z direction) may be perpendicular to one another or may represent different directions that are not perpendicular to one another.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value. When a certain embodiment may be implemented differently, a particular process order may be performed differently from the described order. For example, two consecutively described processes may be performed substantially at the same time or may be performed in an order opposite to the described order.

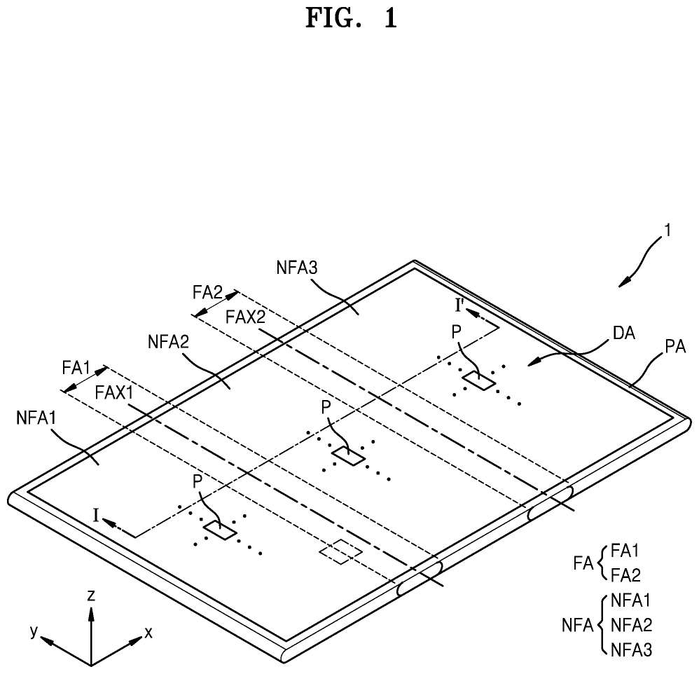

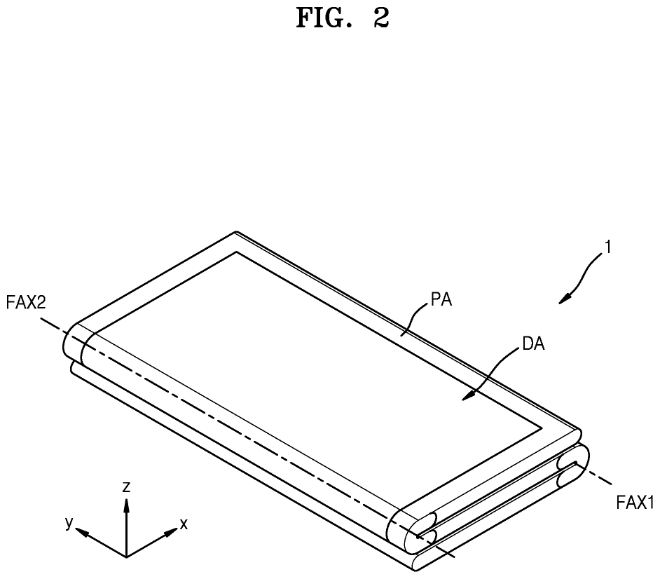

FIG. 1 is a perspective view schematically illustrating a display apparatus according to an embodiment. FIG. 2 is a perspective view schematically illustrating a folded form of a display apparatus according to an embodiment. FIG. 1 is a perspective view illustrating a display apparatus 1 in an unfolded state, and FIG. 2 is a perspective view illustrating the display apparatus 1 in a folded state.

The display apparatus 1 may be an apparatus displaying a moving image or a still image and may be used as a display screen of various products such as televisions, notebook computers, monitors, billboards, and Internet of Things (“IoT”) as well as portable electronic apparatuses such as mobile phones, smart phones, tablet personal computers (“PCs”), mobile communication terminals, electronic notebooks, electronic books, portable multimedia players (“PMPs”), navigations, and Ultra Mobile PCs (“UMPCs”). Also, the display apparatus 1 may be used in wearable devices such as smart watches, watch phones, glasses-type displays, and head-mounted displays (“HMDs”). Also, the display apparatus 1 may be used as a center information display (“CID”) arranged at a vehicle's instrument panel or a vehicle's center fascia or dashboard, a room mirror display replacing a vehicle's side mirror, or a display arranged at a rear side of a vehicle's front seat as an entertainment for a vehicle's rear seat.

As illustrated in FIG. 1, the display apparatus 1 may be unfolded (spread) flat as a whole. The display apparatus 1 may be folded or bent as illustrated in FIG. 2.

In an embodiment, the display apparatus 1 may be folded such that display surfaces thereof may face each other. In another embodiment, the display apparatus 1 may be folded such that the display surface may face outward. Here, the “display surface” may be a surface where an image is displayed, the display surface may include a display area DA and a peripheral area PA, and an image may be provided to the user through the display area DA. Here, the term “folded” may mean that the shape is not fixed but may be modified from the original shape to another shape, and may include being folded along one or more particular lines, that is, a folding axis, curved, or rolled like a scroll.

Referring to FIGS. 1 and 2, the display apparatus 1 may include a display area DA and a peripheral area PA located outside the display area DA. The display area DA may be an area where a plurality of pixels P are arranged to display an image. The peripheral area PA may surround the display area DA and may be a non-display area where pixels P are not arranged.

The display area DA may include a folding area FA and a non-folding area NFA. The folding area FA may be a folding area that is flexible and foldable, and one or more folding areas may be provided. The non-folding area NFA may be a non-folding area that is non-foldable. Here, in an embodiment, an area that is non-foldable will be referred to as a non-folding area; however, this is merely for convenience of description, the expression “non-folding” may include not only a case of being non-flexible and thus being rigid but also a case of being flexible but being less flexible than the folding area and a case of being flexible but being non-foldable. In the folding area FA and the non-folding area NFA, a plurality of pixels P may be arranged to display an image.

The folding area FA may include a first folding area FA1 and a second folding area FA2. The first folding area FA1 may be foldable with respect to a first folding axis FAX1, and the second folding area FA2 may be foldable with respect to a second folding axis FAX2. In an embodiment, the first folding area FA1 and the second folding area FA2 may have similar areas. In another embodiment, the first folding area FA1 and the second folding area FA2 may have different areas.

The non-folding area NFA may include a first non-folding area NFA1, a second non-folding area NFA2, and a third non-folding area NFA3. The first folding area FA1 may be arranged between the first non-folding area NFA1 and the second non-folding area NFA2, and the second folding area FA2 may be arranged between the second non-folding area NFA2 and the third non-folding area NFA3.

Various electronic devices, printed circuit boards, or the like may be electrically attached to the peripheral area PA, and a voltage line or the like for supplying power for driving a display element may be located therein. For example, a scan driver providing a scan signal to each pixel P, a data driver providing a data signal to each pixel P, supply lines (clock signal lines, carry signal lines, driving voltage lines, and/or the like) for signals input to the scan driver and the data driver, and a main power line may be arranged in the peripheral area PA.

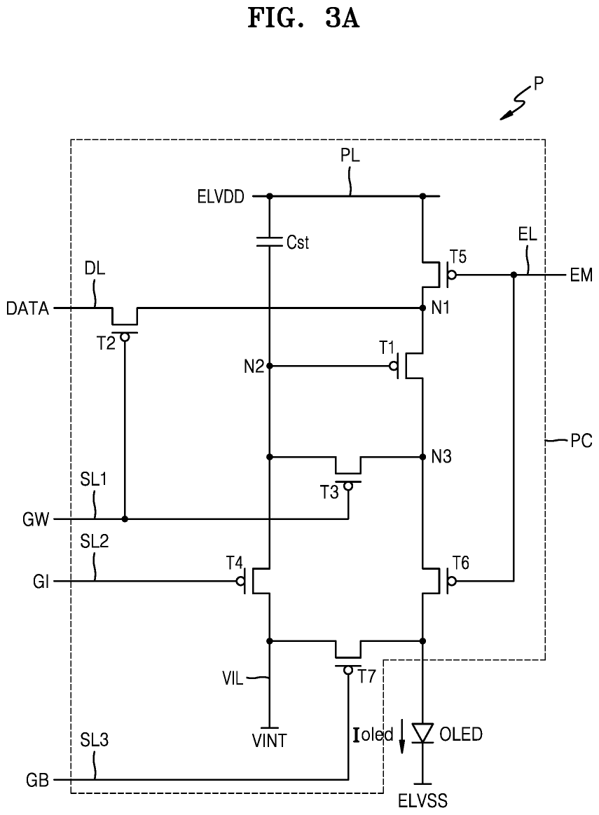

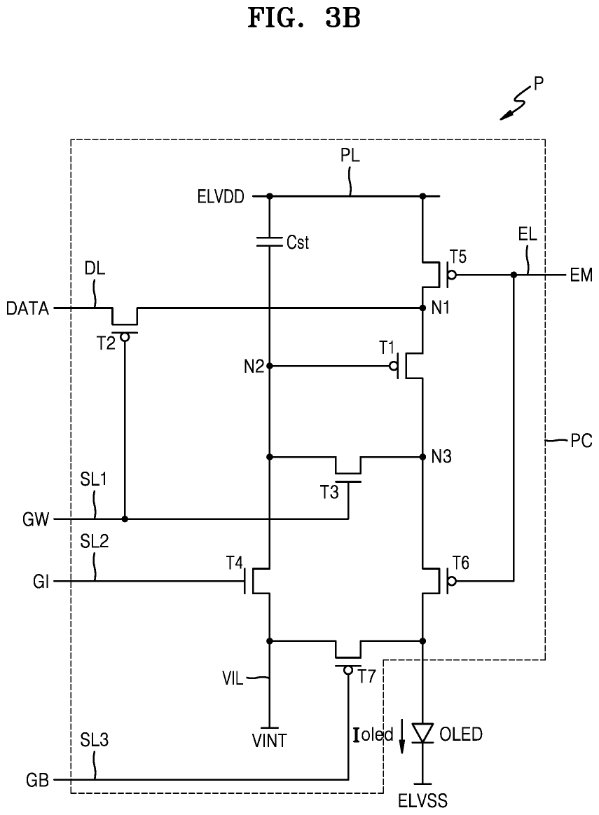

FIGS. 3A and 3B are equivalent circuit diagrams schematically illustrating a pixel circuit arranged in a display panel, respectively.

Referring to FIG. 3A, a pixel circuit PC may include first to seventh transistors T1 to T7. Depending on the type (N type or P type) and/or the operation condition of the transistor, a first terminal of the transistor may be a source electrode or a drain electrode, and a second terminal thereof may be an electrode different from the first terminal. For example, when the first terminal is a source electrode, the second terminal may be a drain electrode.

The pixel circuit PC may be connected to a first scan line SL1 configured to transmit a first scan signal GW, a second scan line SL2 configured to transmit a second scan signal GI, a third scan line SL3 configured to transmit a third scan signal GB, an emission control line EL configured to transmit an emission control signal EM, a data line DL configured to transmit a data signal DATA, a driving voltage line PL configured to transmit a driving voltage ELVDD, and an initialization voltage line VIL configured to transmit an initialization voltage VINT. The pixel circuit PC may be connected to an organic light emitting diode OLED as a display element.

The first transistor T1 may be connected between the driving voltage line PL and the organic light emitting diode OLED. The first transistor T1 may be connected between a first node N1 and a third node N3. The first transistor T1 may be connected to the driving voltage line PL via the fifth transistor T5 and may be electrically connected to the organic light emitting diode OLED via the sixth transistor T6. The first transistor T1 may include a gate electrode connected to a second node N2, a first terminal connected to the first node N1, and a second terminal connected to the third node N3. The driving voltage line PL may be configured to transmit the driving voltage ELVDD to the first transistor T1. The first transistor T1 may function as a driving transistor and may receive the data signal DATA according to a switching operation of the second transistor T2 to supply a driving current Ioled to the organic light emitting diode OLED.

The second transistor T2 (a data writing transistor) may be connected between the data line DL and the first node N1. The second transistor T2 may be connected to the driving voltage line PL via the fifth transistor T5. The second transistor T2 may include a gate electrode connected to the first scan line SL1, a first terminal connected to the data line DL, and a second terminal connected to the first node N1. The second transistor T2 may perform a switching operation of being turned on according to the first scan signal GW received through the first scan line SL1, to transmit the data signal DATA received through the data line DL to the first node N1.

The third transistor T3 (a compensation transistor) may be connected between the second node N2 and the third node N3. The third transistor T3 may be connected to the organic light emitting diode OLED via the sixth transistor T6. The third transistor T3 may include a gate electrode connected to the first scan line SL1, a first terminal connected to the second node N2, and a second terminal connected to the third node N3. The third transistor T3 may be turned on according to the first scan signal GW received through the first scan line SL1 to diode-connect the first transistor T1 to compensate for the threshold voltage of the first transistor T1.

The fourth transistor T4 (a first initialization transistor) may be connected between the second node N2 and the initialization voltage line VIL. The fourth transistor T4 may include a gate electrode connected to the second scan line SL2, a first terminal connected to the second node N2, and a second terminal connected to the initialization voltage line VIL. The fourth transistor T4 may be turned on according to the second scan signal GI received through the second scan line SL2 to transmit the initialization voltage VINT to the gate electrode of the first transistor T1 to initialize the gate electrode of the first transistor T1.

The fifth transistor T5 (a first emission control transistor) may be connected between the driving voltage line PL and the first node N1. The sixth transistor T6 (a second emission control transistor) may be connected between the third node N3 and the organic light emitting diode OLED. The fifth transistor T5 may include a gate electrode connected to the emission control line EL, a first terminal connected to the driving voltage line PL, and a second terminal connected to the first node N1. The sixth transistor T6 may include a gate electrode connected to the emission control line EL, a first terminal connected to the third node N3, and a second terminal connected to a pixel electrode of the organic light emitting diode OLED. The fifth transistor T5 and the sixth transistor T6 may be simultaneously turned on according to the emission control signal EM received through the emission control line EL and thus a driving current may flow through the organic light emitting diode OLED.

The seventh transistor T7 (a second initialization transistor) may be connected between the organic light emitting diode OLED and the initialization voltage line VIL. The seventh transistor T7 may include a gate electrode connected to the third scan line SL3, a first terminal connected to the second terminal of the sixth transistor T6 and the pixel electrode of the organic light emitting diode OLED, and a second terminal connected to the initialization voltage line VIL. The seventh transistor T7 may be turned on according to the third scan signal GB received through the third scan line SL3 to transmit the initialization voltage VINT to the pixel electrode of the organic light emitting diode OLED to initialize the pixel electrode of the organic light emitting diode OLED.

A capacitor Cst may include a first electrode connected to the gate electrode of the first transistor T1 and a second electrode connected to the driving voltage line PL. The capacitor Cst may store and maintain a voltage corresponding to the voltage difference between both ends of the driving voltage line PL and the gate electrode of the first transistor T1 to maintain a voltage applied to the gate electrode of the first transistor T1.

The organic light emitting diode OLED may include a pixel electrode (a first electrode or an anode) and an opposite electrode (a second electrode or a cathode) facing the pixel electrode, and the opposite electrode may receive a common voltage ELVSS. The organic light emitting diode OLED may receive a driving current from the first transistor T1 to emit light to display an image.

FIG. 3A illustrates that the first to seventh transistors T1 to T7 are P-type transistors. However, the present embodiments are not limited thereto. For example, the first to seventh transistors T1 to T7 may be N-type transistors, or some of the first to seventh transistors T1 to T7 may be N-type transistors and the others may be P-type transistors. FIG. 3B illustrates that the third transistor T3 and the fourth transistor T4 among the first to seventh transistors T1 to T7 are N-type transistors and the other transistors are P-type transistors. Here, the third transistor T3 and the fourth transistor T4 may include a semiconductor layer including an oxide, and the other transistors may include a semiconductor layer including silicon.

Moreover, although an organic light emitting diode is used as a display element in the present embodiment, an inorganic light emitting device or a quantum dot light emitting device may be used as a display element in another embodiment.

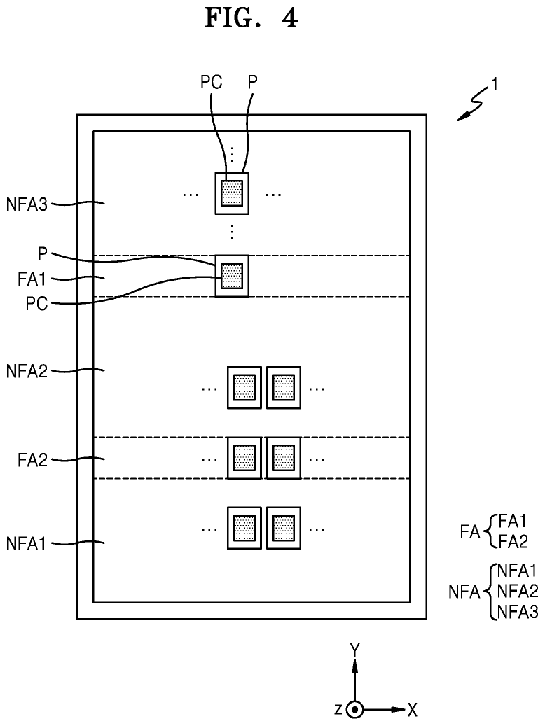

FIG. 4 is a plan view schematically illustrating a pixel circuit and a pixel arranged in a display apparatus according to an embodiment. In FIG. 4, like reference numerals as those in FIG. 1 may denote like members. As used herein, the “plan view” is a view in a thickness direction (z direction) of the display device.

Referring to FIG. 4, the display apparatus 1 may include a folding area FA and a non-folding area NFA. In the present embodiment, a pixel circuit PC having the same size may be arranged in the folding area FA and the non-folding area NFA. That is, the area occupied by one pixel circuit PC may be equal in the folding area FA and the non-folding area NFA. Also, a pixel circuit PC having the same arrangement structure may be arranged in the folding area FA and the non-folding area NFA.

The folding area FA may be vulnerable to an external impact due to a folding operation. Accordingly, the size of the pixel circuit PC arranged in the folding area FA may be less than the size of the pixel circuit PC arranged in the non-folding area NFA, and a distance may be provided between the pixel circuits PC to prevent the pixel circuit PC from being damaged by an external impact. However, when only the size of the pixel circuit PC of the folding area FA is modified, physical characteristics thereof such as parasitic capacitance and resistance may vary from those of the pixel circuit of the non-folding area NFA and thus a line stain may be recognized on a display screen thereof.

In the present embodiment, by applying the pixel circuit PC having the same size and/or the same arrangement structure in the folding area FA and the non-folding area NFA, it may be possible to prepare against an external impact and simultaneously prevent a line stain from being recognized on the display screen.

In the present embodiment, by reducing the size of the pixel circuit PC, the size of one pixel circuit PC may be less than the size of the pixel P driven by the pixel circuit PC. Here, the size of one pixel P may represent the size of an area where one display element emits light. Alternatively, the size of the pixel circuit PC may be less than the size of the pixel electrode of the display element implementing the pixel P.

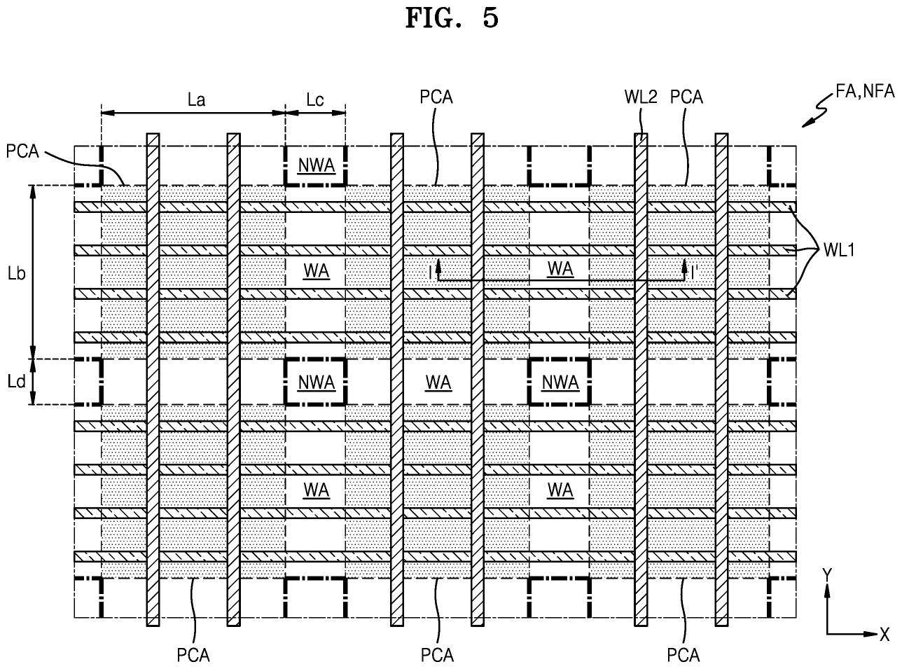

FIG. 5 is a plan view schematically illustrating a pixel circuit area and a line area arranged in a display area of a display apparatus according to an embodiment.

Referring to FIG. 5, the folding area FA and the non-folding area NFA may include a plurality of pixel circuit areas PCA and a line area WA arranged between the plurality of pixel circuit areas PCA. The plurality of pixel circuit areas PCA may be arranged apart from each other with the line area WA therebetween.

In an embodiment, the folding area FA and the non-folding area NFA of the display apparatus may include a plurality of pixel circuit areas PCA having the same structure and a line area WA by which the plurality of pixel circuit areas PCA are spaced apart from each other by a certain distance.

When the size or arrangement structure of the pixel circuit is different between the folding area FA and the non-folding area NFA, the parasitic capacitance or the resistance value of a conductive layer may be nonuniform and thus a line stain may occur in the display apparatus. Thus, because the arrangement structure and the pixel circuit of the folding area FA and the non-folding area NFA have the same structure, the display apparatus may have uniform characteristics on the whole.

The plurality of pixel circuit areas PCA may be repeatedly arranged in the x direction and the y direction. The pixel circuit area PCA may be an area in which a pixel circuit for driving a display element and lines connected to the pixel circuit are arranged. At least one thin film transistor may be arranged in the pixel circuit area PCA. In the pixel circuit area PCA, one pixel circuit PC may be arranged or a plurality of pixel circuits PC may be arranged in a group.

The line area WA may be an area between the plurality of pixel circuit areas PCA, to which the lines connected to the pixel circuit may extend. The line area WA may be an area in which a plurality of lines is arranged and may be an area in which an element such as a thin film transistor or a capacitor constituting a pixel circuit is not arranged.

The line area WA may be arranged on the upper, lower, left, and right sides of one pixel circuit area PCA. First lines WL1 extending in the x direction may be arranged in the y direction, and second lines WL2 extending in the y direction may be arranged in the x direction. Moreover, a non-line area NWA may be arranged between the line areas WA. The non-line area NWA may be an area in which lines or transistors are not arranged. The non-line area NWA may be provided as a plurality of non-line areas NWA, and the plurality of non-line areas NWA may be spaced apart from each other and repeatedly arranged in the x direction and the y direction.

When a display apparatus includes a folding area FA, the possibility of an external impact being transmitted to a pixel circuit PC when the display apparatus is unfolded or folded may increase, and therefore, the area occupied by the pixel circuit PC may be reduced to prevent damage due to an external impact. Accordingly, the present embodiments may prevent damage due to an external impact by increasing the line area WA that is a space between the pixel circuit areas PCA, instead of reducing the area of the pixel circuit area PCA occupied by the pixel circuit PC.

The area of one pixel circuit area PCA in the plan view may be calculated by subtracting the length of a line area WA in which only lines are arranged from the pitch length between adjacent pixel circuits PC among the pixel circuits PC repeatedly arranged in the x direction and the y direction.

The pixel circuit area PCA may have a rectangular shape having a first side having a first length La in the x direction and a second side having a second length Lb in the y direction. In this case, the first length La and the second length Lb may be different from each other. In some embodiments, the first length La and the second length Lb may each have a value of about 45 micrometers (μm) to about 65 μm.

The non-line area NWA may have a rectangular shape having a first side having a third length Lc in the x direction and a second side having a fourth length Ld in the y direction. In this case, the third length Lc and the fourth length Ld may be different from each other. In some embodiments, the third length Lc and the fourth length Ld may each have a value of about 10 μm to about 30 μm.

The third length Lc may be a length by which the pixel circuit areas PCA adjacent in the x direction are spaced apart from each other in the x direction. The fourth length Ld may be a length by which the pixel circuit areas PCA adjacent in the y direction are spaced apart from each other in the y direction.

In some embodiments, the third length Lc may range from about 30% to about 50% of the first length La. In some embodiments, the fourth length Ld may range from about 30% to about 50% of the third length Lc.

In an embodiment, the area occupied by one non-line area NWA may be about 10% or more of the area occupied by one pixel circuit area PCA. For example, the area occupied by one non-line area NWA may range from about 10% to about 25% of the area occupied by one pixel circuit area PCA.

A plurality of lines may be arranged in the display area DA, and the plurality of lines may be arranged in the pixel circuit area PCA and the line area WA. The plurality of lines may include a first line WL1 extending in the x direction and a second line WL2 extending in the y direction. The first line WL1 may be a scan line configured to transmit a scan signal, an emission control line configured to transmit an emission control signal, or an initialization voltage line configured to transmit an initialization voltage. The second line WL2 may be a data line configured to transmit a data signal or a driving voltage line configured to transmit a driving voltage. The first line WL1 and the second line WL2 may be arranged on different layers from each other. The width of the first line WL1 and the width of the second line WL2 may be different from each other in a plan view.

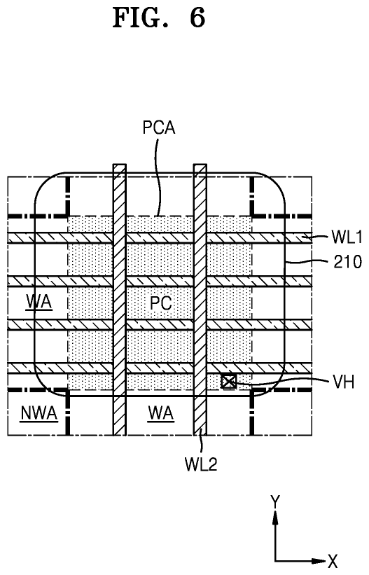

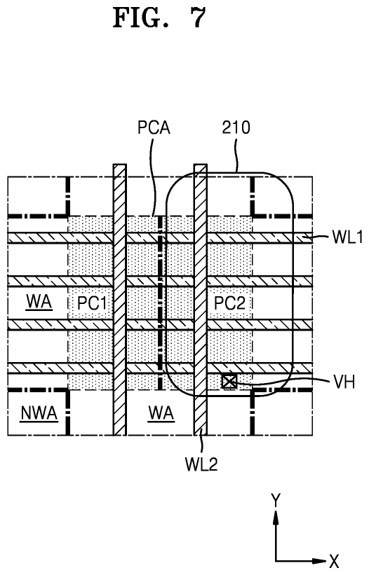

FIGS. 6 and 7 are arrangement diagrams schematically illustrating a form in which a pixel electrode connected to a pixel circuit is arranged according to embodiments.

Referring to FIG. 6, only one pixel circuit PC may be arranged in one pixel circuit area PCA. The pixel circuit PC may be connected to a pixel electrode 210 of a display element. The pixel electrode 210 may be connected to the pixel circuit PC through a via-hole VH. The size of the pixel electrode 210 may be greater than the size occupied by the pixel circuit area PCA. The pixel electrode 210 may be arranged overlapping a line area WA around the pixel circuit area PCA in the plan view.

Referring to FIG. 7, a first pixel circuit PC1 and a second pixel circuit PC2 may be successively arranged in one pixel circuit area PCA. The first pixel circuit PC1 and the second pixel circuit PC2 may have the same structure. However, unlike this, the first pixel circuit PC1 may be symmetrical to the second pixel circuit PC2 with respect to an imaginary line. Each of the first pixel circuit PC1 and the second pixel circuit PC2 may be connected to a pixel electrode 210 of a separate display element. FIG. 7 illustrates only the pixel electrode 210 connected to the second pixel circuit PC2. The pixel electrode 210 may be connected to the second pixel circuit PC2 through a via-hole VH. In some embodiments, a connection electrode or the like may be additionally arranged to connect the pixel electrode 210 with the second pixel circuit PC2.

In the present embodiment, the area occupied by the pixel electrode 210 may be greater than the area occupied by the second pixel circuit PC2 to which the pixel electrode 210 is connected. The pixel electrode 210 may be arranged overlapping a portion of the line area WA and the second pixel circuit PC2 in the plan view.

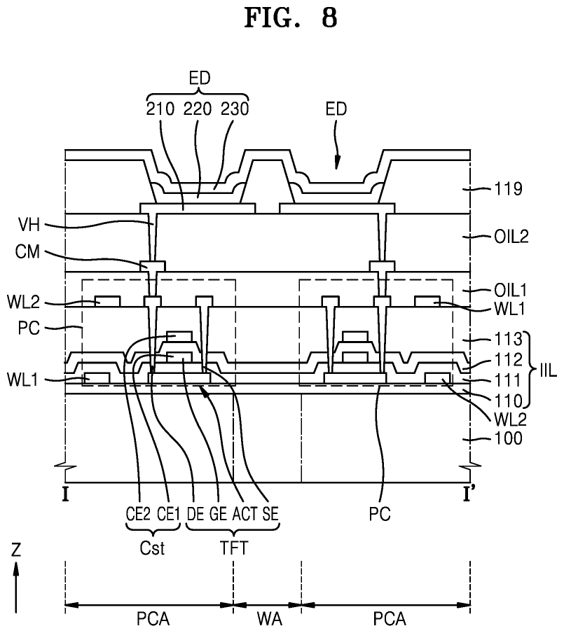

FIG. 8 illustrates, in a cross-sectional view taken along line I-I′ of FIG. 5, a configuration in which an organic light emitting diode is arranged.

Referring to FIG. 8, a substrate 100 may include a plurality of pixel circuit areas PCA and a line area WA arranged between adjacent pixel circuit areas PCA.

A pixel circuit PC may be arranged in the pixel circuit area PCA of the substrate 100, and the pixel circuit PC may include a thin film transistor TFT and a capacitor Cst and may be connected to lines such as a scan line and a data line.

The substrate 100 may be formed of various materials such as metal materials or plastic materials. According to an embodiment, the substrate 100 may be a flexible substrate. The substrate 100 may include a polymer resin such as polyethersulphone (“PES”), polyacrylate (“PAR”), polyetherimide (“PEI”), polyethylene naphthalate (“PEN”), polyethylene terephthalate (“PET”), polyphenylene sulfide (“PPS”), polyimide (“PI”), polycarbonate, cellulose triacetate (“TAC”), or cellulose acetate propionate (“CAP”). In an embodiment, the substrate 100 may have a multilayer structure including a barrier layer and a base layer including the above polymer resin. The barrier layer may include an inorganic material such as silicon nitride (SiNₓ) and/or silicon oxide (SiO₂).

A buffer layer 110 may be disposed over the substrate 100. The buffer layer 110 may include an inorganic insulating material such as silicon nitride (SiNₓ), silicon oxynitride (SiON), and/or silicon oxide (SiO₂) and may include a single layer or multiple layers including the inorganic insulating material.

A semiconductor layer ACT may be disposed over the buffer layer 110. The semiconductor layer ACT may include amorphous silicon, polysilicon, oxide, or organic semiconductor material. The semiconductor layer ACT may include a channel area, a source area, and a drain area.

A first insulating layer 111 may be provided to cover the semiconductor layer ACT. The first insulating layer 111 may include an inorganic insulating material such as silicon oxide (SiO₂), silicon nitride (SiNₓ), silicon oxynitride (SiOₓN_{y}), aluminum oxide (Al₂O₃), or titanium oxide (TiO₂). The first insulating layer 111 may include a single layer or multiple layers including the above inorganic insulating material.

A gate electrode GE may be disposed over the first insulating layer 111 to overlap the semiconductor layer ACT in the plan view. Also, at least one first line WL1 may be further disposed over the first insulating layer 111. In an embodiment, the first line WL1 may be a scan line or an emission control line. The gate electrode GE and the first line WL1 may include molybdenum (Mo), aluminum (Al), copper (Cu), titanium (Ti), or the like and may include a single layer or multiple layers.

A second insulating layer 112 may cover the gate electrode GE. The second insulating layer 112 may include an inorganic insulating material such as silicon oxide (SiO₂), silicon nitride (SiNₓ), silicon oxynitride (SiOₓN_{y}), aluminum oxide (Al₂O₃), or titanium oxide (TiO₂). The second insulating layer 112 may include a single layer or multiple layers including the above inorganic insulating material.

A capacitor Cst may be overlapped over the gate electrode GE in the plan view. The capacitor Cst may include a lower electrode CE1 and an upper electrode CE2. The second insulating layer 112 may be arranged between the lower electrode CE1 and the upper electrode CE2. The gate electrode GE may function not only as the gate electrode of the thin film transistor TFT but also as the lower electrode CE1 of the capacitor Cst. That is, the gate electrode GE and the lower electrode CE1 may be integrated with each other. The upper electrode CE2 may be disposed over the second insulating layer 112 to overlap the lower electrode CE1 at least partially in the plan view.

The upper electrode CE2 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu) and may include a single layer or multiple layers of the above material.

A third insulating layer 113 may cover the upper electrode CE2. The third insulating layer 113 may include silicon oxide (SiO₂), silicon nitride (SiNₓ), silicon oxynitride (SiOₓN_{y}), aluminum oxide (Al₂O₃), titanium oxide (TiO₂), or the like. The third insulating layer 113 may include a single layer or multiple layers including the above inorganic insulating material.

A source electrode SE and a drain electrode DE may be disposed over the third insulating layer 113. The source electrode SE and the drain electrode DE may be connected to the source area and the drain area of the semiconductor layer ACT through contact holes, respectively. Also, a second line WL2 may be disposed over the third insulating layer 113. The source electrode SE, the drain electrode DE, and the second line WL2 may include a conductive material including molybdenum (Mo), aluminum (Al), copper (Cu), titanium (Ti), or the like and may include a single layer or multiple layers including the conductive material. In an embodiment, the source electrode SE and the drain electrode DE may have a three-layer structure of titanium, aluminum, and titanium (Ti/Al/Ti) that are sequentially arranged.

A first organic insulating layer OIL may cover the source electrode SE and the drain electrode DE. A connection electrode CM and/or a signal line (not illustrated) may be disposed over the first organic insulating layer OIL1. The connection electrode CM may be connected to the source electrode SE or the drain electrode DE through a contact hole of the first organic insulating layer OIL1. The connection electrode CM may include a conductive material including molybdenum (Mo), aluminum (Al), copper (Cu), titanium (Ti), or the like and may include a single layer or multiple layers including the conductive material. A second organic insulating layer OIL2 may cover the connection electrode CM.

The first organic insulating layer OIL1 and the second organic insulating layer OIL2 may include an organic insulating material such as a general-purpose polymer, a polymer derivative having a phenolic group, an acrylic polymer, an imide-based polymer, an aryl ether-based polymer, an amide-based polymer, a fluorine-based polymer, a p-xylene-based polymer, a vinyl alcohol-based polymer, or any blend thereof.

Display elements ED may be disposed over the second organic insulating layer OIL2. The display element ED may include a pixel electrode 210, an emission layer 220, and an opposite electrode 230.

The pixel electrode 210 may be disposed over the second organic insulating layer OIL2. The pixel electrode 210 may be connected to the pixel circuit PC by being connected to the connection electrode CM through a via-hole VH passing through the second organic insulating layer OIL2. The pixel electrode 210 may be arranged in at least a portion of the line area WA and the pixel circuit area PCA.

The pixel electrode 210 may be a (semi)transparent electrode or a reflective electrode. For example, the pixel electrode 210 may include a reflective layer including Ag, Mg, Al, Pt, Pd, Au, Ni, Nd, Ir, Cr, or any compound thereof and a transparent or semitransparent electrode layer located over the reflective layer. The transparent or semitransparent electrode layer may include at least one of indium tin oxide (“ITO”), indium zinc oxide (“IZO”), zinc oxide (ZnO), indium oxide (In₂O₃), indium gallium oxide (“IGO”), and aluminum zinc oxide (“AZO”). For example, the pixel electrode 210 may have a three-layer structure of ITO/Ag/ITO.

A pixel definition layer 119 may be disposed over the second organic insulating layer OIL2. The pixel definition layer 119 may cover the edge of the pixel electrode 210 and may define a pixel by including an opening through which a portion of the pixel electrode 210 is exposed. That is, the size and shape of the emission area may be defined by the opening of the pixel definition layer 119. The opening of the pixel definition layer 119 may correspond to a center area of the pixel electrode 210. The pixel definition layer 119 may be formed of an organic insulating material such as polyimide, polyamide, acrylic resin, benzocyclobutene, hexamethyldisiloxane (“HMDSO”), or phenol resin by spin coating or the like. In some embodiments, the pixel definition layer 119 may include an insulating material (e.g., an organic insulating material) including a black pigment or dye to prevent color mixing between adjacent pixels to improve visibility.

The emission layer 220 may include a high molecular weight material or a low molecular weight material and may emit red, green, blue, or white light. A first common layer (not illustrated) and/or a second common layer (not illustrated) may be disposed under and over the emission layer 220, respectively. The first common layer may be a component disposed under the emission layer 220 and may include, for example, a hole transport layer (“HTL”) or may include an HTL and a hole injection layer (“HIL”). The second common layer may be a component disposed over the emission layer 220 and may include an electron transport layer (“ETL”) and/or an electron injection layer (“EIL”). In some embodiments, the second common layer may be omitted.

While the emission layer 220 is arranged for each pixel to correspond to the opening of the pixel definition layer 119, each of the first common layer and the second common layer may be a common layer integrally formed to entirely cover the display area DA of the substrate 100 like the opposite electrode 230 described below.

The opposite electrode 230 may be disposed over the emission layer 220. The opposite electrode 230 may include a conductive material having a low work function. For example, the opposite electrode 230 may include a (semi)transparent layer including silver (Ag), magnesium (Mg), aluminum (Al), platinum (Pt), lithium (Li), calcium (Ca), or any alloy thereof. Alternatively, the opposite electrode 230 may further include a layer such as ITO, IZO, ZnO, or In₂O₃ over the (semi)transparent layer including the above material. The opposite electrode 230 may be integrally formed in a plurality of display elements to correspond to a plurality of pixel electrodes 210.

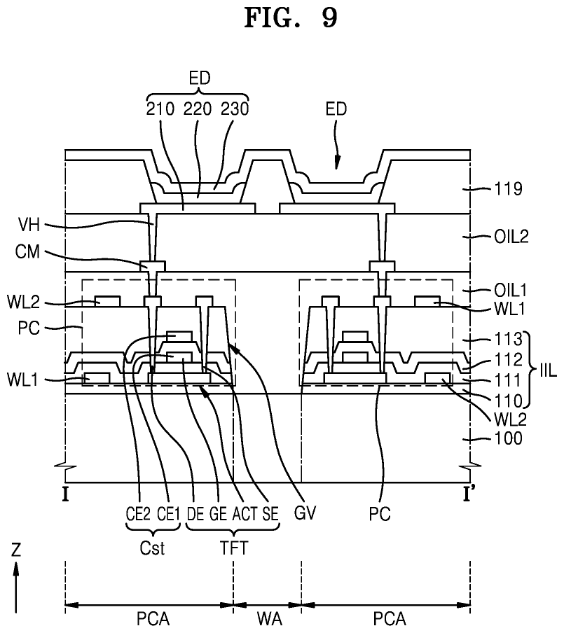

FIG. 9 is a cross-sectional view schematically illustrating a display apparatus according to an embodiment. In FIG. 9, like reference numerals as those in FIG. 8 may denote like members.

Referring to FIG. 9, a substrate 100 may include a plurality of pixel circuit areas PCA and a line area WA arranged between adjacent pixel circuit areas PCA.

The display apparatus according to an embodiment may include an inorganic insulating layer IIL defining a groove GV therein corresponding to the line area WA.

When a buffer layer 110, a first insulating layer 111, a second insulating layer 112, and a third insulating layer 113 are collectively referred to as an inorganic insulating layer IIL, the inorganic insulating layer IIL may define a groove GV or an opening therein. The groove GV may have a shape in which a portion of the inorganic insulating layer IIL is removed. In an embodiment, the groove GV of the inorganic insulating layer IIL may be arranged in the line area WA. Alternatively, the groove GV may be provided between adjacent pixel circuit areas PCA.

The opening of the buffer layer 110, the opening of the first insulating layer 111, the opening of the second insulating layer 112, and the opening of the third insulating layer 113 may overlap each other to form the groove GV in the plan view. The opening of the buffer layer 110, the opening of the first insulating layer 111, the opening of the second insulating layer 112, and the opening of the third insulating layer 113 may be separately formed through separate processes or may be simultaneously formed through the same process. When the opening of the buffer layer 110, the opening of the first insulating layer 111, the opening of the second insulating layer 112, and the opening of the third insulating layer 113 are separately formed through separate processes, the groove GV may have a step like a stair shape.

Moreover, contact holes through which a conductive layer formed subsequent to the third insulating layer 113 contacts a lower conductive layer (e.g., a semiconductor layer, a gate electrode, an upper electrode of a capacitor, a scan line, or the like) may be defined in at least one of the first insulating layer 111, the second insulating layer 112, and the third insulating layer 113. The contact holes may be formed simultaneously with the formation of the groove GV.

A first organic insulating layer OIL1 may be formed on the entire surface of the substrate 100 while filling the groove GV. Because the first organic insulating layer OIL1 is arranged in the groove GV, a stress or crack due to the folding of the display apparatus may be prevented from propagating to other pixel areas.

In the above embodiments, a structure in which the display apparatus is folded twice by including two folding areas has been described; however, this is merely an example, and in other embodiments, the display apparatus may include one or more folding areas and the entire display apparatus may correspond to the folding area in the case of a display apparatus that is rolled like a scroll.

As described above, according to the present embodiments, because the line area is arranged between the pixel circuit areas, the reliability and display quality of the display apparatus may be improved.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a substrate including pixel circuit areas, line areas arranged between the pixel circuit areas, and non-line areas which are arranged between the line areas and in which no line is arranged;
a pixel circuit arranged in the pixel circuit areas and comprising at least one thin film transistor;
a plurality of lines arranged in the pixel circuit areas and the line areas; and
a display element including a pixel electrode connected to the pixel circuit,
wherein in a plan view an area of the pixel electrode is greater than an area in which the pixel circuit is arranged.

2. The display apparatus of claim 1, wherein the pixel circuit areas and the line areas are alternately arranged in a first direction and a second direction intersecting with the first direction.

3. The display apparatus of claim 1, wherein an area of one of the non-line areas is about 10 percentages (%) or more of an area of one of the pixel circuit areas in the plan view.

4. The display apparatus of claim 1, wherein the display apparatus includes a folding area and a non-folding area, and
in the plan view, an area of one of the pixel circuit areas in the folding area is the same as an area of one of the pixel circuit areas in the non-folding area.

5. The display apparatus of claim 1, wherein each of the pixel circuit areas includes two pixel circuits.

6. The display apparatus of claim 1, further comprising an inorganic insulating layer defining a groove therein in the line areas.

7. The display apparatus of claim 1, wherein the pixel electrode at least partially overlaps the line areas in the plan view.

8. The display apparatus of claim 1, wherein the plurality of lines comprises a first line extending in a first direction and a second line extending in a second direction intersecting with the first direction,
the first line is arranged in a same layer as a gate electrode of the thin film transistor, and
the second line is arranged in a different layer from the first line.

9. The display apparatus of claim 8, wherein the second line is arranged farther from an upper surface of the substrate than the first line in a thickness direction.

10. The display apparatus of claim 8, wherein the first line comprises a scan line, and the second line comprises a data line.

11. A display apparatus including a folding area and a non-folding area, the display apparatus comprising:
a substrate including pixel circuit areas, line areas arranged between the pixel circuit areas, and non-line areas which are arranged between the line areas and in which no line is arranged;
a pixel circuit arranged in the pixel circuit areas and comprising at least one thin film transistor;
a plurality of lines arranged in the pixel circuit areas and the line areas; and
a display element including a pixel electrode connected to the pixel circuit,
wherein in a plan view an area of one of the pixel circuit areas in the folding area is the same as an area of one of the pixel circuit areas in the non-folding area.

12. The display apparatus of claim 11, wherein an area of the pixel electrode is greater than an area in which the pixel circuit is arranged in the plan view.

13. The display apparatus of claim 11, wherein the pixel circuit areas and the line areas are alternately arranged in a first direction and a second direction intersecting with the first direction.

14. The display apparatus of claim 11, wherein an area of one of the non-line areas is about 10% or more of an area of one of the pixel circuit areas in the plan view.

15. The display apparatus of claim 11, wherein each of the pixel circuit areas includes two pixel circuits.

16. The display apparatus of claim 11, further comprising an inorganic insulating layer defining a groove therein in the line areas.

17. The display apparatus of claim 11, wherein the pixel electrode at least partially overlaps the line areas in the plan view.

18. The display apparatus of claim 11, wherein the plurality of lines comprises a first line extending in a first direction and a second line extending in a second direction intersecting with the first direction,
the first line is arranged in a same layer as a gate electrode of the thin film transistor, and
the second line is arranged in a different layer from the first line.

19. The display apparatus of claim 18, wherein the second line is arranged farther from an upper surface of the substrate than the first line in a thickness direction.

20. The display apparatus of claim 18, wherein the first line comprises a scan line, and the second line comprises a data line.
